(19) United States
(12) Patent Application Publication
(10) Pub. No.: US 2026/0118782 A1
(43) Pub. Date: Apr. 30, 2026

(54) OPTICAL SYSTEM AND LITHOGRAPHY SYSTEM

(71) Applicant: Carl Zeiss SMT GmbH, Oberkochen (DE)

(72) Inventors: Oliver HERBST, Aalen (DE); Markus HOLZ, Aalen (DE); Thomas Wolfsteiner, Aalen (DE)

(21) Appl. No.: 19/430,758

(22) Filed: Dec. 23, 2025

Related U.S. Application Data
(63) Continuation of application No. PCT/EP2024/065767, filed on Jun. 7, 2024.

(30) Foreign Application Priority Data
Jun. 28, 2023 (DE) 10 2023 206 069.8

(51) Int. Cl. G03F 7/00

(52) U.S. Cl. CPC G03F 7/70991; G03F 7/70141; G03F 7/70258

(57) ABSTRACT

An optical system comprises a plurality of actuable optical elements and a plurality of actuator/sensor devices for actuating and/or sensing the optical elements. The optical system has a supply device for providing a supply voltage for a number of electrical loads of the optical system. The supply device has a parallel connection of a plurality N, where N≥3, of supply rails with a respective power supply unit. The respective power supply unit of the N supply rails is configured to provide a predetermined power supply unit output power on the output side at a supply node in fault-free operation of the supply device and to provide

$$\frac{N}{N - 1}$$

times the predetermined power supply unit output power at the supply node in faulty operation.

### CROSS-REFERENCE TO RELATED APPLICATIONS

The present application is a continuation of, and claims benefit under 35 USC 120 to, international application No. PCT/EP2024/065767, filed Jun. 7, 2024, which claims benefit under 35 USC 119 of German Application No. 10 2023 206 069.8, filed Jun. 28, 2023. The entire disclosure of each of these applications is incorporated by reference herein.

### FIELD

The present disclosure relates to an optical system comprising a supply device for providing a supply voltage for a number of electrical loads of the optical system, and to a lithography apparatus comprising such an optical system.

### BACKGROUND

Microlithography apparatuses having actuable optical elements, such as for example microlens arrays or micromirror arrays, are known. Microlithography is used to produce microstructured components, such as for example integrated circuits. The microlithography process is carried out using a lithography apparatus having an illumination system and a projection system.

Driven by the desire for ever smaller structures in the production of integrated circuits, EUV lithography apparatuses that use light at a wavelength in the range of 0.1 nm to 30 nm, for example 13.5 nm, are currently being developed. Since, in general, most materials absorb light at this wavelength, such EUV lithography apparatuses typically use reflective optical units, that is to say mirrors, instead of refractive optical units, that is to say lenses, as used previously.

The image of a mask (reticle) illuminated via the illumination system is projected here via the projection system onto a substrate, for example a silicon wafer, which is coated with a light-sensitive layer (photoresist) and is arranged in the image plane of the projection system, in order to transfer the mask structure to the light-sensitive coating of the substrate. Actuable optical elements can be used to improve the imaging of the mask on the substrate. By way of example, wavefront aberrations during exposure, which result in magnified and/or blurred image representations, are able to be compensated for.

For example, a MEMS actuator (MEMS; microelectromechanical system) or a PMN actuator (PMN; lead magnesium niobate) can be used as actuator. A PMN actuator can help enable path positioning in the sub-micrometer or sub-nanometer range. In this case, the actuator, having actuator elements stacked one on top of another, may experience a force that causes a specific linear expansion as a result of a DC voltage being applied. The position set by way of the DC voltage (DC; direct current) may be adversely affected by external electromechanical crosstalk at the resonance points of the actuator controlled by the DC voltage that arise as a matter of principle. MEMS mirrors and actuators suitable for controlling them are described for example in DE 10 2016 213 025 A1.

Lithography apparatuses are, in general, highly complex systems comprising a large number of actuators to be controlled. Control of the actuators can place very high demands on fail-safety of the voltage supply provided by a supply device. The probability of a failure in such a system can be high. Therefore, it can be desirable to ensure that a failure of a subcomponent does not mean total failure of the system.

In addition, the installation space for the supply device for providing the voltage supply within the lithography apparatus can be severely limited. In order to increase fail-safety, a redundant interconnection of a plurality of power supply units is conventionally used.

However, a redundant interconnection of power supply units usually involves keeping more power supply unit power available. In this case, the power supply unit power can be correlated with the installation space. More power supply unit power therefore generally involves more installation space. As a consequence, normally redundant interconnection of power supply units generally involves keeping double the power supply unit power available, which in turn can lead to a doubling of the installation space.

Furthermore, a short circuit of one load can cause a collapse of the voltage supply for all the other loads. In addition, a short circuit of a component or power supply unit in the voltage supply path of the supply device can cause a collapse of the entire voltage supply.

### SUMMARY

The present disclosure seeks to improve the supply of electrical loads of the optical system.

According to a first aspect, an optical system comprising a plurality of actuable optical elements and a plurality of actuator/sensor devices for actuating and/or sensing the optical elements is proposed. The optical system comprises a supply device for providing a supply voltage for a number of electrical loads of the optical system. The supply device comprises a parallel connection of a plurality N, where N≥3, of supply rails with a respective power supply unit. In this case, the respective power supply unit of the N supply rails is configured to provide a predetermined power supply unit output power on the output side at a supply node in fault-free operation of the supply device and to provide

$$\frac{N}{N - 1}$$

times the predetermined power supply unit output power at the supply node in faulty operation.

With the present supply device for the optical system, power supply units can be intelligently redundantly interconnected, so that it can be possible to achieve an optimum of reliability and installation space.

In addition, the interconnection formed by the present parallel connection of the plurality N, where N≥3, of supply rails with a respective power supply unit can help ensure that the failure of a single power supply unit in the path of the voltage supply allows continued operation without restriction. This can result in increased fail-safety compared with a normal voltage supply. The failure of one load can be tolerated and for example may have no influence on the voltage supply of the other loads.

In fault-free operation of the supply device, the respective supply rail provides

$$\frac{1}{N}$$

of the total output power of the supply device on the output side.

Faulty operation of the supply device is characterized in that one, for example exactly one, of the supply rails is faulty and cannot provide its predetermined power supply unit output power on the output side. In faulty operation of the supply device, the respective supply rail, except for the faulty supply rail, provides

$$\frac{N}{N - 1}$$

times the predetermined power supply unit output power on the output side. For example, if the predetermined power supply unit output power is 25% of the total output power of the supply device, then

$$\frac{N}{N - 1}$$

times for this example is 33% of the total output power of the supply device. Consequently, the respective supply rail, except for the faulty supply rail, provides 33% of the total output power of the supply device on the output side in faulty operation of the supply device. This can compensate for the failure of the faulty supply rail and provides the same electrical power at the input node of the load both in fault-free operation of the supply device and in faulty operation of the supply device.

The supply rail can also be referred to as a rail or as a supply path. A failure of a component in part of a supply path does not result in a failure of the voltage supply. For example, the current desired by the load is divided approximately equally among the remaining supply paths. The actuator is for example a MEMS actuator, a capacitive actuator, for example a PMN actuator (PMN; lead magnesium niobate), or a PZT actuator (PZT; lead zirconate titanate), or a LiNbO3 (lithium niobate) actuator. The actuator is configured for example to actuate an optical element of the optical system. Examples of such an optical element comprise lenses, mirrors and adaptive mirrors.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and denotes a wavelength of the operating light of between 0.1 nm and nm. The projection exposure apparatus can also be a DUV lithography apparatus. DUV stands for “deep ultraviolet” and denotes a wavelength of the operating light of between 30 nm and 250 nm.

According to one embodiment, the respective power supply unit is designed such that it provides as maximum output power at most 180%, such as at most 150%, for example at most 120%, of

$$\frac{N}{N - 1}$$

times the predetermined power supply unit output power. This can result in an optimum in regard to reliability of the supply device and the installation space for the supply device.

According to one embodiment, the respective power supply unit is embodied as a DC/DC converter or as an AC/DC converter.

According to one embodiment, the N supply rails are coupled on the input side to an input node of the supply device for receiving an input voltage. In this case, the respective supply rail can have a respective fuse coupled between the power supply unit of the supply rail and the input node. The fuse can protect the input voltage supply in the event of a fault in the supply path. The respective power supply unit can be configured to convert the input voltage received at the input node into the supply voltage. In embodiments, the power supply unit also converts the input voltage received at the input node into the supply voltage in a plurality of steps.

According to one embodiment, the respective load is coupled to M supply rails of the N supply rails of the supply device, where M≤N. In this case, the respective load can have an input node for receiving the power supply unit output powers provided by the M coupled supply rails.

According to one embodiment, a series connection formed by an electronic fuse and a diode is connected between the respective supply node of the supply device and the input node of the load.

The electronic fuse can also be referred to as E-fuse and can provide the functions of overcurrent shutdown and/or overvoltage protection. The diode can act for example as a current valve and permits the current flow only in the direction of the load.

In the event of a short circuit of a load, the electronic fuse assigned to the load can disconnect the defective load from the voltage supply. It is thus possible to ensure that the voltage supply for the other loads is available without restriction.

According to one embodiment, the respective load is coupled to all supply rails of the N supply rails of the supply device, where M=N.

According to one embodiment, the respective load is coupled to a subset M of the N supply rails of the supply device, where M<N, such as where M=0.5*N, for example M=2. M=2 means the least outlay for simple redundancy.

According to one embodiment, an interface device is provided, which is configured to couple the loads to the M supply rails of the N supply rails of the supply device.

According to one embodiment, the respective load is coupled, for example is connected, to a first subset of the N supply rails in fault-free operation of the supply device and is coupled, for example is connected, to a second subset of the N supply rails in faulty operation of the supply device. The second subset of the N supply rails can comprise exclusively such supply rails which are fault-free even in faulty operation of the supply device and can thus provide their predetermined power supply unit output power at their supply node.

According to one embodiment, the interface device is configured to couple, for example to connect, the respective load to the first subset of the N supply rails in fault-free operation of the supply device and to couple, for example to connect, the respective load to the second subset of the N supply rails in faulty operation of the supply device.

According to one embodiment, the respective load is coupled, for example connectable, to a main supply rail of the N supply rails and to a backup supply rail of the N supply rails. If the main supply rail of a load fails, this load can be supplied with electrical power via the backup supply rail.

According to one embodiment, the respective main supply rail of the respective load is assigned a respective backup supply rail of the N supply rails. In this case, the interface device can be configured to connect the load to the assigned backup supply rail in the event of failure of the main supply rail of the load. The interface device thus can help ensure that each load is coupled to a functioning supply rail, either the main supply rail or in the event of a fault the backup supply rail, for the purpose of electrical power supply.

According to one embodiment, the optical system is embodied as an illumination optical unit or as a projection optical unit of a lithography apparatus.

The optical system can comprise for example a micromirror array and/or a microlens array having a multiplicity of mutually independently actuable optical elements. These are examples of the electrical loads that can be supplied with electrical energy by the present supply device.

According to one embodiment, the optical system has a vacuum housing, in which the actuable optical elements, the actuator/sensor devices and the supply device are arranged.

According to a second aspect, a lithography apparatus is proposed, having an optical system according to the first aspect or according to one of the embodiments of the first aspect.

The lithography apparatus is for example an EUV lithography apparatus, the operating light of which is in a wavelength range of 0.1 nm to 30 nm, or a DUV lithography apparatus, the operating light of which is in a wavelength range of 30 nm to 250 nm.

“A” or “an” or “one” in the present case should not necessarily be understood as restrictive to exactly one element. Rather, a plurality of elements, such as for example two, three or more, can also be provided. Nor should any other numeral used here be understood to the effect that there is a restriction to exactly the stated number of elements. Rather, numerical deviations upward and downward are possible, unless indicated otherwise.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further features, configurations and aspects of the disclosure are the subject matter of the dependent claims and also of the exemplary embodiments of the disclosure that are described below. The disclosure is explained in greater detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic illustration of one embodiment of an optical system;

FIG. 3 shows a schematic block diagram of a first embodiment of a supply device of an optical system;

FIG. 4 shows the supply device according to FIG. 3 in the event of a fault and its subsequent reaction;

FIG. 5 shows a schematic block diagram of a second embodiment of a supply device of an optical system;

FIG. 6 shows a schematic block diagram of a third embodiment of a supply device of an optical system;

FIG. 7 shows a schematic block diagram of a fourth embodiment of a supply device of an optical system;

FIG. 8 shows the supply device according to FIG. 7 in the event of a fault and its subsequent reaction;

FIG. 9 shows a schematic block diagram of a fifth embodiment of a supply device of an optical system; and

FIG. 10 shows the supply device according to FIG. 9 in the event of a fault and its subsequent reaction.

### DETAILED DESCRIPTION

In the figures, identical or functionally identical elements have been provided with the same reference signs, unless indicated otherwise. Furthermore, it should be noted that the illustrations in the figures are not necessarily true to scale.

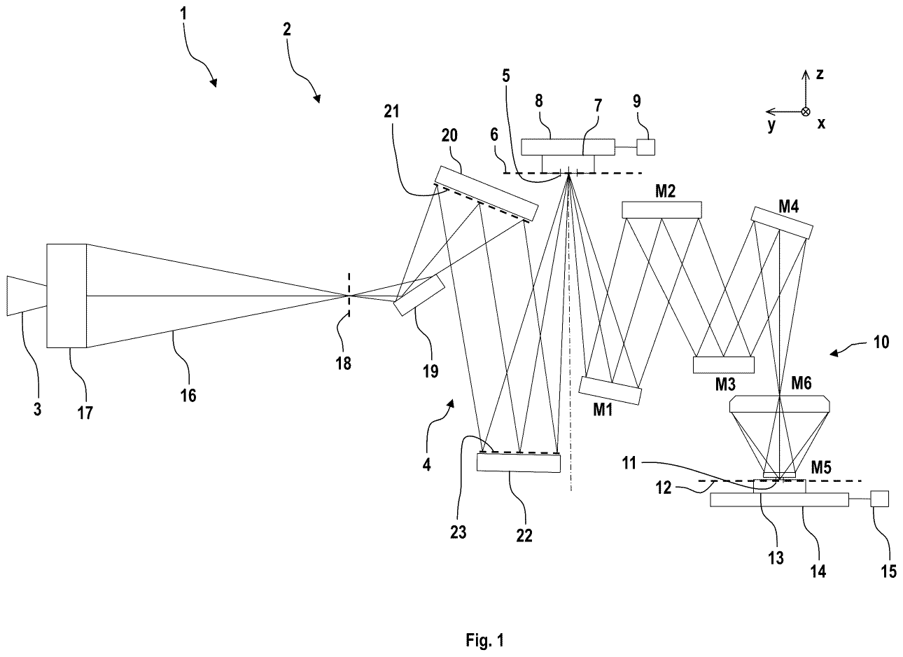

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction y. The displacement, firstly, of the reticle 7 by way of the reticle displacement drive 9 and, secondly, of the wafer 13 by way of the wafer displacement drive can be implemented so as to be synchronized with one another.

The light source 3 is an EUV radiation source. The light source 3 emits for example EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be a free electron laser (FEL).

The illumination radiation 16 emanating from the light source 3 is focused by a collector 17. The collector 17 can be a collector with one or with a plurality of ellipsoidal and/or hyperboloidal reflection surfaces. The at least one reflection surface of the collector 17 can be impinged on by the illumination radiation 16 with grazing incidence (GI), i.e. with angles of incidence greater than 45°, or with normal incidence (NI), i.e. with angles of incidence less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can represent a separation between a radiation source module, having the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the pure deflection effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, for example as rectangular facets or as facets with an arcuate or partly circular edge contour. The first facets 21 can be embodied as plane facets or alternatively as convexly or concavely curved facets.

As is known from DE 10 2008 009 600 A1, for example, the first facets 21 themselves can each also be composed of a multiplicity of individual mirrors, for example a multiplicity of micromirrors. The first facet mirror 20 can be embodied for example as a microelectromechanical system (MEMS system). For details, reference is made to DE 10 2008 009 600 A1.

The illumination radiation 16 travels horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be desirable to arrange the second facet mirror 22 not exactly in a plane that is optically conjugate to a pupil plane of the projection optical unit 10. For example, the second facet mirror 22 can be arranged so as to be tilted in relation to a pupil plane of the projection optical unit 10, as described for example in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In an embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror, or alternatively two or more mirrors arranged one behind another in the beam path of the illumination optical unit 4. The transfer optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In an embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is regularly only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and for example can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

The projection optical unit 10 can be embodied for example in anamorphic fashion. For example, it has different imaging scales Bx, By in the x-direction x and y-direction y. The two imaging scales Bx, By of the projection optical unit 10 can be (Bx, By)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, that is to say in a direction perpendicular to the scanning direction.

The projection optical unit 10 leads to a reduction in size of 8:1 in the y-direction y, that is to say in the scanning direction.

Other imaging scales are likewise possible. Imaging scales with the same mathematical sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 in order to form a respective illumination channel for illuminating the object field 5. For example, this can result in illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 can comprise for example a homocentric entrance pupil. The latter can be accessible. It can also be inaccessible.

The entrance pupil of the projection optical unit 10 regularly cannot be exactly illuminated using the second facet mirror 22. In the case of imaging by the projection optical unit 10 that telecentrically images the center of the second facet mirror 22 onto the wafer 13, the aperture rays often do not intersect at a single point. However, it is possible to find an area in which the spacing of the aperture rays that is determined in pairs becomes minimal. This area constitutes the entrance pupil or an area conjugate thereto in real space. For example, this area exhibits a finite curvature.

It may be the case that the projection optical unit 10 has different poses of the entrance pupil for the tangential beam path and for the sagittal beam path. In this case, an imaging element, for example an optical component of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

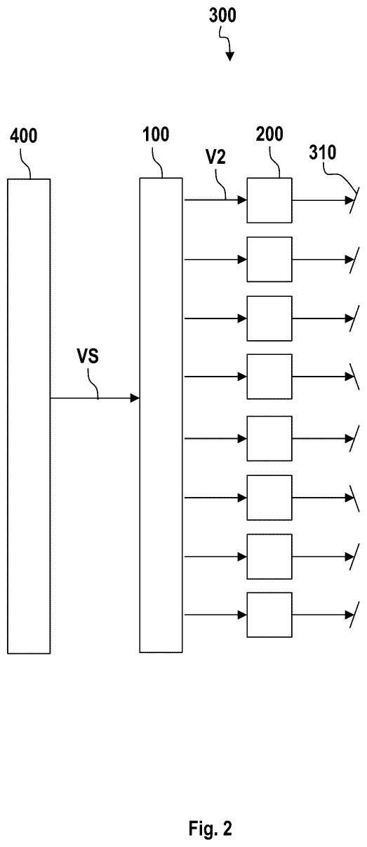

FIG. 2 shows a schematic illustration of one embodiment of an optical system 300 for a lithography apparatus or projection exposure apparatus 1, as shown for example in FIG. 1. Additionally, the optical system 300 in FIG. 2 can also be used in a DUV lithography apparatus, for example.

The optical system 300 in FIG. 2 has a plurality of actuable optical elements 310. The optical system 300 is embodied here as a micromirror array, wherein the optical elements 310 are micromirrors. Each micromirror 310 is actuable via an assigned actuator 200. The actuator 200 is one example of an actuator/sensor device for actuating and/or sensing the optical elements 310. By way of example, a respective micromirror 310 can be tilted about two axes and/or displaced in one, two or three spatial axes via the assigned actuator 200. The reference signs only of the topmost row of these elements are depicted, for reasons of clarity.

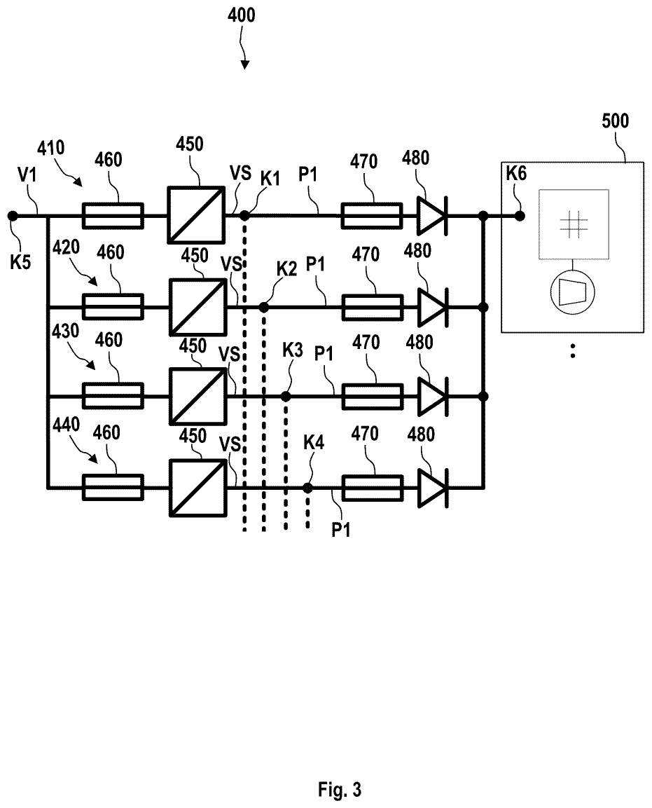

The control device 100 controls the respective actuator 200, for example with a control voltage V2. A position of the respective micromirror 310 is thus set. The control device 100 is supplied with electrical energy by a supply device 400. In this case, the supply device 400 of the control device 100 provides a supply voltage VS. The control device 100 is one example of an electrical load of the optical system 300. Examples of the supply device 400 are described with reference to FIGS. 3 to 10.

In this case, FIG. 3 shows a schematic block diagram of a first embodiment of a supply device 400 of an optical system 300. The supply device 400 is configured to provide a supply voltage VS for a number of electrical loads 500. Without restriction of generality, the number of electrical loads 500 is equal to one in FIG. 3.

The supply device 400 comprises a parallel connection of a plurality N, where N≥3, of supply rails 410-440. Without restriction of generality, N=4 in FIG. 3. The supply rail 410-440 can also be referred to as a rail. The respective supply rail 410-440 comprises a respective power supply unit 450. The respective power supply unit 450 is configured to provide a predetermined power supply unit output power P1 on the output side at a supply node K1-K4 in fault-free operation of the supply device 400 and to provide

$$\frac{N}{N - 1}$$

times P2 the predetermined power supply unit output power at the supply node K1-K4 in faulty operation of the supply device 400.

As shown in FIG. 3, the N supply rails 410-440 are coupled on the input side to an input node K5 of the supply device 400 for receiving an input voltage V1. The respective supply rail 410-440 has a fuse 460 coupled between the power supply unit 450 of the supply rail 410-440 and the input node K5. The respective power supply unit 450 is configured to convert the input voltage V1 received at the input node K5 into the supply voltage VS. The respective power supply unit 450 is embodied for example as a DC/DC converter or as an AC/DC converter. For example, the respective power supply unit 450 is designed such that it provides as maximum output power at most 180%, such as at most 150%, for example at most 120%, of

$$\frac{N}{N - 1}$$

times P2 the predetermined power supply unit output power. This affords an optimum in regard to reliability of the supply device 400 and the installation space for the supply device 400.

A series circuit formed by an electronic fuse 470 and a diode 480 is connected between the respective supply node K1-K4 of the supply device 400 and the input node K6 of the load 500.

In fault-free operation of the supply device 400, the respective supply rail 410-440 provides

$$\frac{1}{N}$$

of the total output power of the supply device 440 on the output side. For example, if N=4 and the total output power is designated as 100%, the respective supply rail 410-440 provides one quarter (25%) of the total output power. Fault-free operation of the supply device 400 is characterized in that all N supply rails 410-440 are fault-free and the respective supply rail 410-440 can provide its predetermined power supply unit output power P1 of for example 25% of the total output power of the supply device 400 on the output side.

Faulty operation of the supply device 400 is characterized in that one, for example exactly one, of the supply rails 410-440 is faulty and cannot provide its predetermined power supply unit output power P1 on the output side. In faulty operation of the supply device 400, the respective supply rail 410-440, except for the faulty supply rail, provides

$$\frac{N}{N - 1}$$

times P2 the predetermined power supply unit output power on the output side. If, as explained above, the predetermined power supply unit output power is 25% of the total output power of the supply device 400 (P1=25%), then

$$\frac{N}{N - 1}$$

times P2 for this example is 33% of the total output power of the supply device 400 (P2=33%). In other words, the respective supply rail 410-440, except for the faulty supply rail, provides 33% of the total output power of the supply device 400 on the output side in faulty operation of the supply device 400.

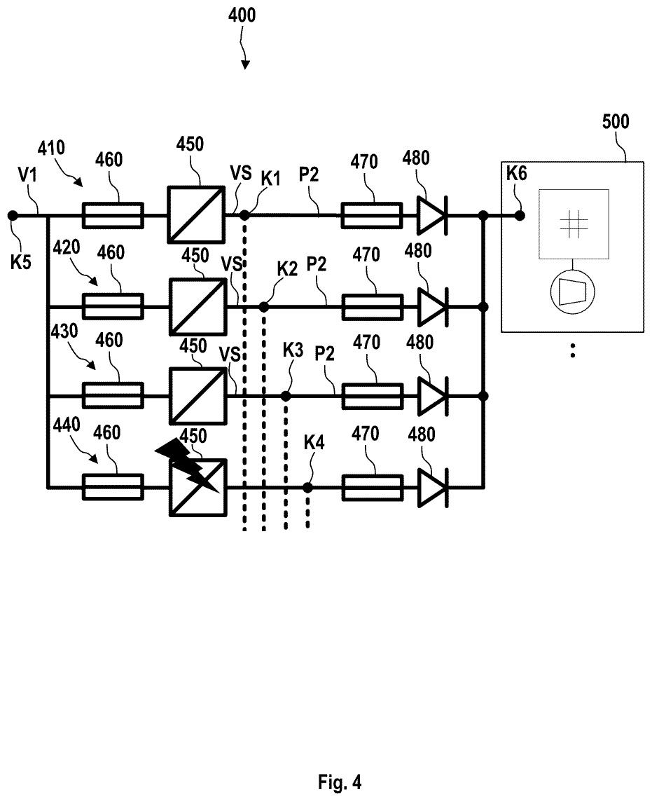

This is clarified by a comparison of FIGS. 3 and 4. FIG. 3 shows the first embodiment of the supply device 400 in fault-free operation, whereas FIG. 4 shows the first embodiment of the supply device 400 in faulty operation.

As shown in FIG. 3, in fault-free operation of the supply device 400, the respective supply rail 410-440 provides the predetermined power supply unit output power P1, which is for example 25% of the total output power of the supply device 400, on the output side at the respective supply node K1-K4. If, as shown in FIG. 4, one of the supply rails fails, in the example in FIG. 4 the supply rail 440, this faulty supply rail 440 provides no power on the output side. The faulty supply rail 440 in FIG. 4 is marked with an arrow indicating the fault in FIG. 4. As furthermore shown in FIG. 4, the remaining fault-free supply rails 410, 420, 430 provide

$$\frac{N}{N - 1}$$

times P2 the predetermined power supply unit output power, i.e. in the present case 33% of the total output power of the supply device 400, at the respective supply node K1-K3. Thus, in FIG. 3 and FIG. 4, the identical electrical power is provided at the node K6, which is the input node of the load 500. In the example in FIG. 3, each of the supply rails 410-440 delivers 25% of the total output power, whereas in the example in FIG. 4 the three upper supply rails 410, 420, 430 each provide 33% of the total output power of the supply device 400 at the node K6. Thus, as illustrated in FIG. 4, the failure of the faulty supply rail 440 is compensated for.

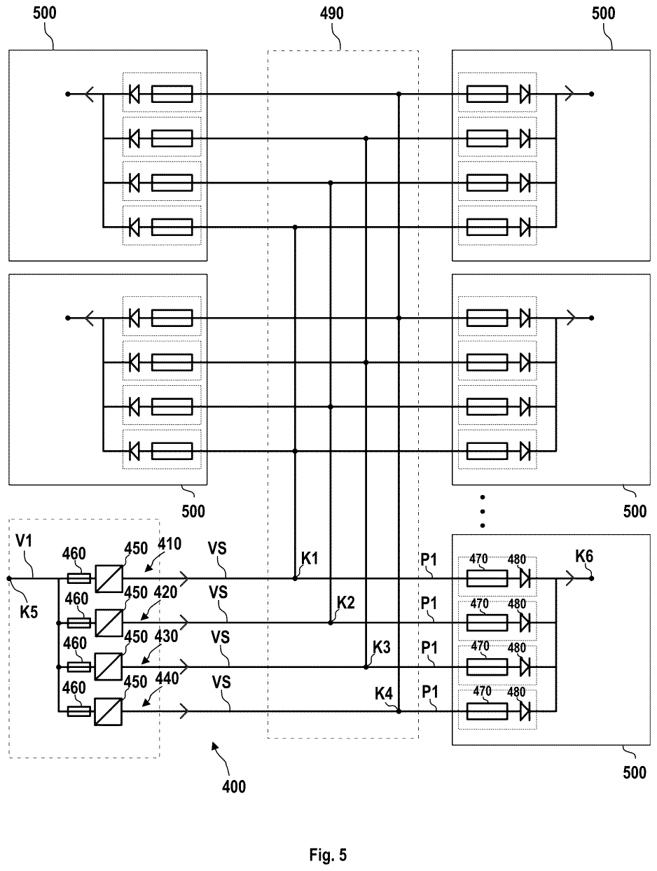

FIG. 5 illustrates a schematic block diagram of a second embodiment of a supply device 400 of an optical system 300. The supply device 400 in FIG. 5 is based on the first embodiment of the supply device 400 in FIGS. 3 and 4 and comprises for example all its features. As shown in FIG. 5, the supply device 400 supplies a large number of loads 500 with power. The number of loads 500 is purely by way of example and can be very large in embodiments, for example a few dozen or a few hundred. Since FIG. 5 shows fault-free operation of the supply device 400, all supply rails 410-440 of the supply device 400 provide the predetermined power supply unit output power P1 on the output side. Since it is also the case in FIG. 5 that N=4, the predetermined power supply unit output power P1 is for example 25% of the total output power of the supply device 400. Faulty operation of the supply device 400 according to FIG. 5 corresponds to that described in respect of FIGS. 3 and 4.

For reasons of clarity, in regard to the respective load 500 to the right of the input node K6, no further components or devices are depicted, since they are not necessary in the present case for the understanding of the disclosure. The respective electronic fuse 470 and the respective diode 480 are assigned to the respective load 500 in the present case. Since the structure of the respective load 500 in FIG. 5 in the direction of the supply device 400 with the components 470 and 480 is in each case identical, only the bottommost load 500 in FIG. 5 is provided with respective reference signs.

In general, the respective load 500 is coupled to M supply rails 410-440 of the N supply rails 410-440 of the supply device 400, where M≤N. As illustrated in FIG. 5, an interface device 490 can be provided. The interface device 490 is configured to couple the loads 500 to the M supply rails 410-440 of the N supply rails 410-440 of the supply device 400.

In this case, the respective load 500 has an input node K6 for receiving the power supply unit output powers P1 provided by the M coupled supply rails 410-440. In the embodiment according to FIG. 5, M=N, and so the respective load 500 is coupled to all supply rails 410-440 of the supply device 400.

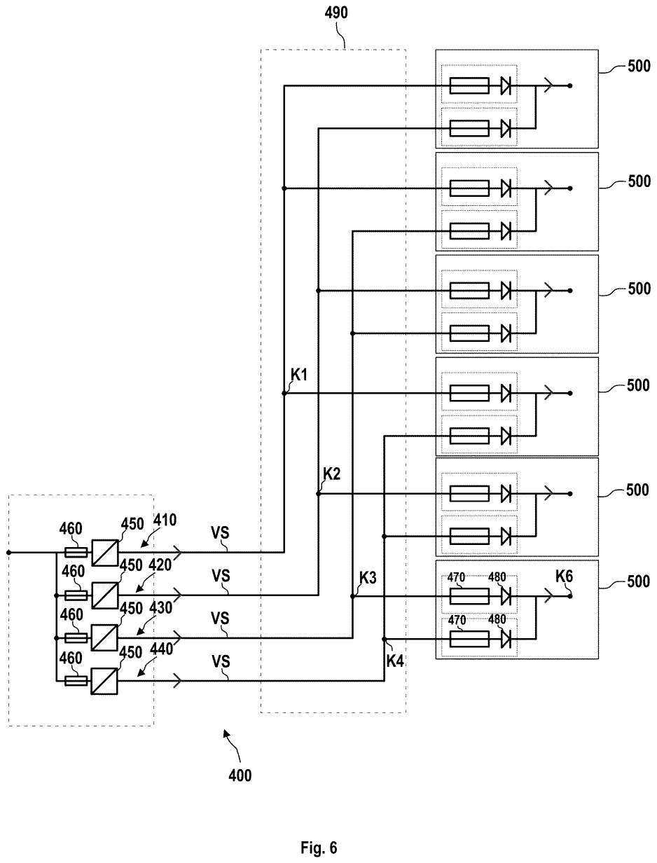

With respect to that, a different coupling between loads 500 and the supply device 400 is shown in FIG. 6. In FIG. 6, six loads 500 are supplied with electrical power by the supply device 400. In this case, the respective load 500 in FIG. 6 is coupled to a subset M of the N supply rails 410-440 of the supply device 400. In the exemplary embodiment in FIG. 6, N=4 and M=2. Therefore, M=0.5*N in FIG. 6.

With regard to the choice of the number of loads 500 which are supplied with electrical power by the supply device 400, the following rule can be applied:

$$\frac{N !}{( N - M ) ! * M !}$$

where N denotes the number of supply rails of the supply device 400 and M denotes the number of those supply rails to which the respective load 500 is coupled. For the present example in FIG. 6 where N=4 and M=2, the following result is produced upon applying the above rule for an optimized choice of the number of loads 500:

$$\frac{4 !}{( 4 - 2 ) ! * 2 !} = 6$$

According to this rule and as explained above, the supply device 400 in FIG. 6 supplies six loads 500.

In detail, the first load 500 (from the top) in FIG. 6 is supplied via the supply rails 410 and 420, the second load 500 is supplied via the supply rails 410 and 430, the third load 500 is supplied via the supply rails 420 and 430, the fourth load 500 is supplied via the supply rails 410 and 440, the fifth load 500 is supplied via the supply rails 420 and 440, and the sixth load 500 is supplied via the supply rails 430 and 440.

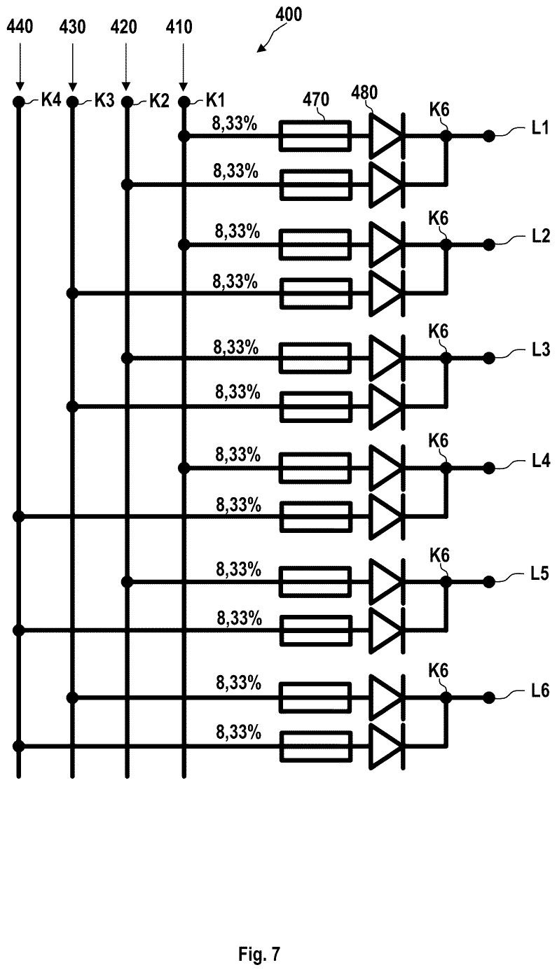

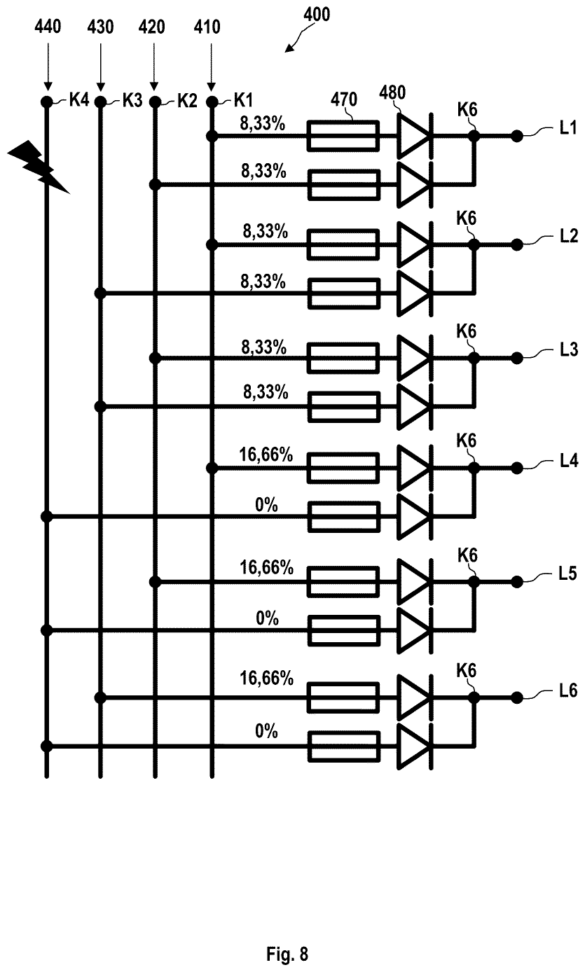

FIG. 7 shows a schematic block diagram of a fourth embodiment of a supply device 400 of an optical system 300, and FIG. 8 shows the supply device 400 according to FIG. 7 in the event of a fault and its subsequent reaction.

FIG. 7 and FIG. 8 illustrate the supply rails 410-440 of the supply device 400 merely schematically by way of their reference signs 410-440 and the supply nodes K1-K4. In detail, the supply device 400 is constructed as in the abovementioned exemplary embodiments.

As is further shown in FIG. 7, the supply device 400 in FIG. 7 supplies six loads L1-L6, wherein the respective load L1-L6 is coupled to two supply rails (M=2) of the N supply rails 410-440 (N=4). In this case, the load L1 is supplied via the supply rails 410 and 420, the load L2 is supplied via the supply rails 410 and 430, the load L3 is supplied via the supply rails 420 and 430, the load L4 is supplied via the supply rails 410 and 440, the load L5 is supplied via the supply rails 420 and 440, and the load L6 is supplied via the supply rails 430 and 440.

If, as explained above, the total output power of the supply device is 100%, each of the supply device 410-440 provides 25% of the total output power of the supply device 400 in fault-free operation. If, as illustrated in FIG. 7, 25% of the total output power is provided at the respective supply node K1-K4 and three of the loads L1-L6 are attached to the respective supply node K1-K4, then the respective load draws one third of the 25% of the total output power of the supply device 400 provided at the supply node K1-K4 and thus 8.33% (rounded) of the total output power of the supply device 400 (25%: 3=8.33%). The supply of the respective load L1-L6 by the fault-free supply rails 410-440 according to FIG. 7 is summarized in Table 1 below.

TABLE 1

| | Load | | | | | | |
|---|---|---|---|---|---|---|---|
| Supply rail | L1 | L2 | L3 | L4 | L5 | L6 | Total |
| Supply rail 410 | 8.33% | 8.33% | — | 8.33% | — | — | 25% |
| Supply rail 420 | 8.33% | — | 8.33% | — | 8.33% | — | 25% |
| Supply rail 430 | — | 8.33% | 8.33% | — | — | 8.33% | 25% |
| Supply rail 440 | — | — | — | 8.33% | 8.33% | 8.33% | 25% |

If, as shown in FIG. 8, the supply rail 440 fails, it cannot provide electrical power for the connected loads L4, L5 and L6. This is then undertaken by the fault-free supply rails 410-430, as shown in FIG. 8. Consequently, in FIG. 8, the load L4 is supplied exclusively via the supply rail 410, the load L5 is supplied exclusively via the supply rail 420, and the load L6 is supplied exclusively via the supply rail 430. The supply of the respective load L1-L6 by the fault-free supply rails 410-430 according to FIG. 8 is presented in Table 2 below.

TABLE 2

| | Load | | | | | | |
|---|---|---|---|---|---|---|---|
| Supply rail | L1 | L2 | L3 | L4 | L5 | L6 | Total |
| Supply rail | 8.33% | 8.33% | — | 16.66% | — | — | 33.33% |
| 410 | | | | | | | |
| Supply rail | 8.33% | — | 8.33% | — | 16.66% | — | 33.33% |
| 420 | | | | | | | |
| Supply rail | — | 8.33% | 8.33% | — | — | 16.66% | 33.33% |
| 430 | | | | | | | |
| Supply rail | — | — | — | — | — | — | — |
| 440 | | | | | | | |

Table 2 also shows that the fault-free supply rails 410, 420 and 430 jointly provide the total output power of the supply device 400 (33.33%+33.33%+33.33%=100%).

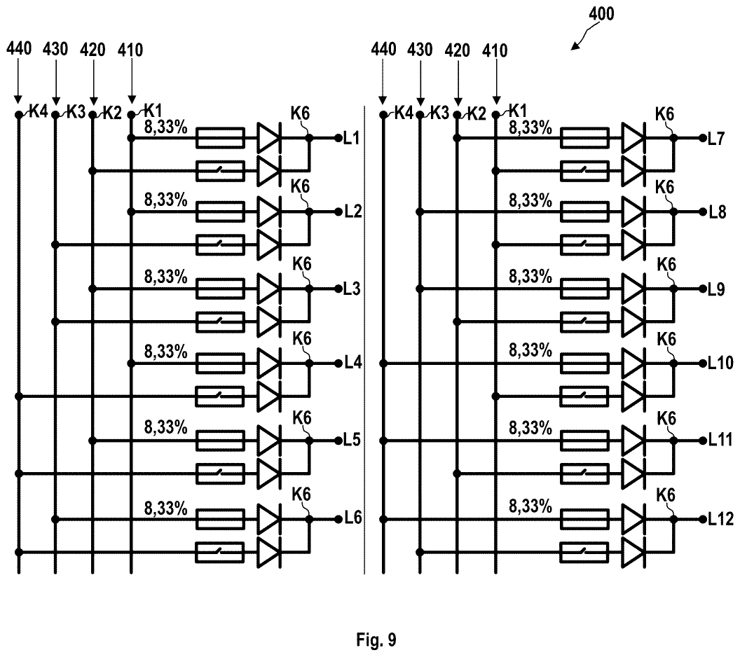

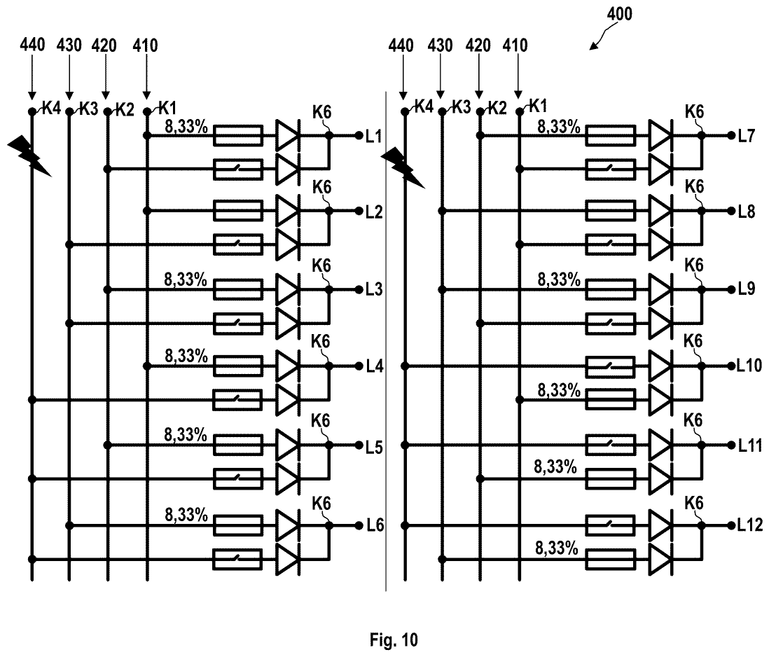

FIG. 9 shows a schematic block diagram of a fifth embodiment of a supply device 400 of an optical system 300, and FIG. 10 shows the supply device 400 according to FIG. 9 in the event of a fault and its subsequent reaction. FIG. 9 and FIG. 10 illustrate the supply rails 410-440 of the supply device 400 merely schematically by way of their reference signs 410-440 and the supply nodes K1-K4. In detail, the supply device 400 is constructed as in the abovementioned exemplary embodiments. In addition, FIG. 9 shows for example that the respective load L1-L12 is coupled to a main supply rail of the N supply rails 410-440 and to a backup supply rail of the N supply rails 410-440. Table 3 below shows the coupling of the respective load L1-L12 to its respective main supply rail and its respective backup supply rail.

TABLE 3

| Load | Main supply rail | Backup supply rail |
|---|---|---|
| L1 | 410 | 420 |
| L2 | 410 | 430 |
| L3 | 420 | 430 |
| L4 | 410 | 440 |
| L5 | 420 | 440 |
| L6 | 430 | 440 |
| L7 | 420 | 410 |
| L8 | 430 | 410 |
| L9 | 430 | 420 |
| L10 | 440 | 410 |
| L11 | 440 | 420 |
| L12 | 440 | 430 |

As shown in Table 3 above, the load L1 has the supply rail 410 as the main supply rail and the supply rail 420 as the backup supply rail. The load L2 has the supply rail 410 as the main supply rail and the supply rail 430 as the backup supply rail. The further assignments for the loads L3-L12 are revealed analogously by Table 3 above.

Table 3 above thus also shows that a respective backup supply rail is assigned to the respective main supply rail of the respective load L1-L12. In this case, the interface device (not shown in FIG. 9 and FIG. 10) is configured to connect the load L1-L12 to the assigned backup supply rail in the event of failure of the main supply rail of the load L1-L12.

For the present example, it is assumed that the supply rail 440 (see FIG. 10) has failed. In fault-free operation of the supply device 400, the supply rail 440 supplied the loads L10, L11 and L12. Since this is no longer possible after failure of the supply rail 440, as shown in FIG. 10, the load L10 is supplied via the backup supply rail 410, the load L11 is supplied via the backup supply rail 420, and the load L12 is supplied via the backup supply rail 430.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Control device
200 Actuator
300 Optical system
310 Optical element
400 Supply device
410 Supply rail (rail)
420 Supply rail (rail)
430 Supply rail (rail)
440 Supply rail (rail)
450 Power supply unit
460 Fuse
470 Electronic fuse
480 Diode
490 Interface device
500 Load
K1 Supply node
K2 Supply node
K3 Supply node
K4 Supply node
K5 Input node of the supply device
K6 Input node of the load
L1 Load
L2 Load
L3 Load
L4 Load
L5 Load
L6 Load
L7 Load
L8 Load
L9 Load
L10 Load
L11 Load
L12 Load
M1 Mirror
M2 Mirror
M3 Mirror
M4 Mirror
M5 Mirror
M6 Mirror
P1 Predetermined power supply unit output power
P2

$$\frac{N}{N - 1}$$

times the predetermined power supply unit output power
VS Supply voltage
V1 Input voltage
V2 Control voltage

What is claimed is:

1. An optical system, comprising:
a plurality of actuable optical elements;
a plurality of actuator/sensor devices for actuating and/or sensing the optical elements;
a supply device configured to provide a supply voltage for a number of electrical loads of the optical system,
wherein:
the supply device comprises a plurality N of parallel connected supply rails;
N≥3;
for each of the N supply rails, the supply rail comprises a power supply unit having an output side; and
for each of the N supply rails, the power supply unit is configured to provide:
in fault-free operation of the supply device, a predetermined power supply unit output power at a supply node on an output side of the power supply unit; and
in faulty operation,
$$\frac{N}{N - 1}$$
times the predetermined power supply unit output power at the supply node.

2. The optical system of claim 1, wherein, for each of the N supply rails, the power supply unit is configured to provide a maximum output power of at most 180% of
$$\frac{N}{N - 1}$$
times the predetermined power supply unit output power at the supply node.

3. The optical system of claim 1, wherein, for each of the N supply rails, the power supply unit comprises a DC/DC converter or an AC/DC converter.

4. The optical system of claim 1, wherein:
the N supply rails are coupled on an input side to an input node to receive an input voltage;
for each of the N supply rails, the supply rail comprises a fuse coupled between the power supply unit and the input node; and
for each of the N supply rails, the power supply unit is configured to convert the input voltage received at the input node into the supply voltage.

5. The optical system of claim 1, wherein for each of the number of electrical loads:
the electrical load is coupled to M supply rails of the N supply rails;
M≤N;
the electrical load has an input node to receive the power supply unit output power provided by each of the M coupled supply rails.

6. The optical system of claim 5, wherein, for each of the number of electrical loads, the supply device comprises a series connection comprising an electronic fuse and a diode connected between the supply node and the input node of the electrical load.

7. The optical of claim 5, wherein, for each of the number of electrical loads, M=N.

8. The optical system of claim 5, wherein, for each of the number of electrical loads, M<N.

9. The optical system of claim 5, wherein the supply device further comprises an interface device configured to couple each of the number of electrical loads to the M supply rails.

10. The optical system of claim 1, wherein, for each of the number of electrical loads, the electrical load is coupled:
to a first subset of the N supply rails in fault-free operation of the supply device; and
to a second subset of the N supply rails in faulty operation of the supply device.

11. The optical system of claim 10, wherein, for each of the number of electrical loads, an interface device is configured to couple:
the electrical load to the first subset of the N supply rails in fault-free operation of the supply device; and
the electrical load to the second subset of the N supply rails in faulty operation of the supply device.

12. The optical system of claim 1, wherein, for each of the number of electrical loads, the electrical load is coupled to a main supply rail of the N supply rails and to a backup supply rail of the N supply rails.

13. The optical system of claim 12, wherein, for each of the number of electrical loads:
a main supply rail of the electrical load is assigned a backup supply rail of the N supply rails; and
an interface device is configured to connect the electrical load to the assigned backup supply rail when the main supply rail of the electrical load fails.

14. The optical system of claim 1, wherein the optical system is an illumination optical unit of a lithography apparatus.

15. The optical system of claim 1, wherein the optical system is a projection optical unit of a lithography apparatus.

16. An apparatus, comprising:
an optical unit according to claim 1,
wherein the apparatus is a lithography apparatus.

17. The apparatus of claim 1, further comprising:
an illumination optical unit; and
a projection optical unit,
wherein:
the illumination optical unit is configured to illuminate an object field in an object plane of the projection optical unit;
the projection optical unit is configured to image the object field into an image field in an image plane of the projection optical unit; and
the illumination optical unit comprises the optical system.

18. The apparatus of claim 1, further comprising:
an illumination optical unit; and
a projection optical unit,
wherein:
the illumination optical unit is configured to illuminate an object field in an object plane of the projection optical unit;
the projection optical unit is configured to image the object field into an image field in an image plane of the projection optical unit; and
the projection optical unit comprises the optical system.

19. A method of using a lithography apparatus comprising an illumination optical unit and a projection optical unit, the method comprising:
using the illumination optical unit to illuminate an object field in an object plane of the projection optical unit; and
using the projection optical unit to image the object field into an image field of an image plane of the projection optical unit,
wherein the illumination optical unit comprises an optical unit according to claim 1.

20. A method of using a lithography apparatus comprising an illumination optical unit and a projection optical unit, the method comprising:
using the illumination optical unit to illuminate an object field in an object plane of the projection optical unit; and
using the projection optical unit to image the object field into an image field of an image plane of the projection optical unit,
wherein the projection optical unit comprises an optical unit according to claim 1.
